(19) United States
(12) Patent Application Publication
(10) Pub. No.: US 2012/0309175 A1
(43) Pub. Date: Dec. 6, 2012

(54) VAPOR-PHASE GROWTH SEMICONDUCTOR SUBSTRATE SUPPORT SUSCEPTOR, EPITAXIAL WAFER MANUFACTURING APPARATUS, AND EPITAXIAL WAFER MANUFACTURING METHOD

(75) Inventor: Hisashi Masumura, Nishishirakawa (JP)

(73) Assignee: SHIN-ETSU HANDOTAI CO., LTD., Tokyo (JP)

(21) Appl. No.: 13/578,174

(22) PCT Filed: Jan. 28, 2011
(86) PCT No.: PCT/JP2011/000462

§ 371 Date: Aug. 9, 2012

(30) Foreign Application Priority Data
Feb. 25, 2010 (JP) 2010-040313

(51) Int. Cl. H01L 21/20

(52) U.S. Cl. 438/478; 257/E21.09

(57) ABSTRACT

According to the present invention, there is provided a vapor-phase growth semiconductor substrate support susceptor for supporting a semiconductor substrate at the time of vapor-phase growth, wherein the susceptor comprises a pocket portion in which the semiconductor substrate is arranged and has a taper portion having a taper formed such that an upper surface of the susceptor is inclined upwards or downwards from an edge of the pocket portion to an outer side. As a result, there can be provided the susceptor for supporting the semiconductor substrate at the time of vapor-phase growth that can improve flatness of an epitaxial wafer by controlling a layer thickness of an epitaxial layer at a peripheral portion on a main front surface side of the epitaxial wafer, and the epitaxial wafer manufacturing apparatus using this susceptor.

### TECHNICAL FIELD

The present invention relates to a susceptor used for supporting a semiconductor substrate in a vapor-phase growth process, an epitaxial wafer manufacturing apparatus using this susceptor, and an epitaxial wafer manufacturing method.

### BACKGROUND ART

Vapor-phase growth of an epitaxial layer (e.g., a silicon epitaxial layer) on a main front surface of a semiconductor substrate is carried out by arranging a susceptor in a reaction vessel, arranging a substrate on this susceptor, heating the substrate to a desired growth temperature by a heating device in this state, and supplying a source gas onto the main front surface of the substrate by a gas supply device.

The thus formed epitaxial wafer has damage-free surface of very good quality with less defects.

In recent years, silicon epitaxial wafers have begun to be adopted in an MOS FET such as an MPU, a DRAM, or a flash memory, a power device such as an IGBT, or an imaging device such as a CCD or CIS.

Further, high integration and miniaturization of devices have advanced for realization of a high yield and high performance, and not only substrate surface quality but also flatness of a substrate is particularly important.

Furthermore, a region where the flatness is assured for the purpose of improving a yield of a device has spread from a region excluding 5 mm of an outer periphery to a region excluding 3 mm of an outer periphery or 2 mm of an outer periphery.

Here, in regard to epitaxial growth of a silicon wafer demanding very high flatness, using an apparatus of batch processing to single wafer processing has enabled improving layer thickness uniformity of an epitaxial layer.

However, when a substrate before epitaxial growth is not flat, a layer thickness distribution of an epitaxial layer must be adjusted in accordance with a shape of the substrate before the growth rather than simply forming the epitaxial layer having a uniform layer thickness.

For example, in case of a silicon wafer, a substrate before epitaxial growth is subjected to a polishing treatment to be flattened, and hence high flatness is achieved at a central portion of the silicon wafer. However, sufficient flatness is not achieved at a peripheral portion, and flatness must be improved by adjusting a layer thickness of the peripheral portion during an epitaxial growth process.

For such a problem, there is a method for adjusting a depth of a pocket portion of the susceptor.

Furthermore, for example, as described in Patent Document 1, there has been also suggested a method for providing a plurality of injectors for supplying a source gas to the center and a peripheral portion of a substrate, adjusting concentration or a flow amount of the source gas supplied from each injector to control layer thicknesses of an epitaxial layer at the central portion and the peripheral portion of the silicon wafer, thereby achieving flatness.

Moreover, as described in Patent Document 2, for example, there has been also suggested a method for changing a length of a region called ledge where a susceptor and a silicon wafer back side are in proximity to or in contact with each other to form an epitaxial layer on a back surface of a silicon wafer peripheral portion as well and selectively controlling a shape of the silicon wafer peripheral portion.

### CITATION LIST

### Patent Documents

Patent Document 1: Japanese Unexamined Patent Application Publication No. H06-232060

Patent Document 2: Japanese Unexamined Patent Application Publication No. 2007-273623

### SUMMARY OF INVENTION

However, the method for adjusting a depth of a pocket portion has a problem that a step is produced between the wafer edge and the susceptor, a flow of the gas is disturbed, and the layer thickness is changed in not only the edge portion but also a region on the inner side of the wafer.

Moreover, the method for adjusting, e.g., a flow amount of the source gas from each injector described in Patent Document 1 has a problem that a layer thickness of the epitaxial layer cannot be selectively controlled at the peripheral portion alone of the silicon wafer that serves as the substrate since the source gas diffuses.

Additionally, the method described in Patent Document 2 has a problem of, e.g., complexity and lack of stability since a shape of the peripheral portion is formed by adding a layer thickness distribution of the epitaxial layer on a front surface side of the silicon wafer and a layer thickness distribution of the epitaxial layer on a back surface side of the same. Further, control over the shape is unsuccessful, the wafer outer peripheral portion may become wavy to greatly deteriorate flatness.

Therefore, in view of the above-described problems, it is an object of the present invention to provide a susceptor which is configured to support a semiconductor substrate at the time of vapor-phase growth that can improve flatness of an epitaxial wafer by controlling a layer thickness of an epitaxial layer at a peripheral portion on a main front surface side of the epitaxial wafer, and to provide a manufacturing apparatus and a manufacturing method of an epitaxial wafer using this susceptor.

To solve the problems, according to the present invention, there is provided a vapor-phase growth semiconductor substrate support susceptor for supporting a semiconductor substrate at the time of vapor-phase growth, wherein the susceptor comprises a pocket portion in which the semiconductor substrate is arranged and has a taper portion having a taper formed such that an upper surface of the susceptor is inclined upwards or downwards from an edge of the pocket portion to an outer side.

Using the susceptor having the taper portion provided with the taper, where the upper surface of the susceptor gradually inclines upwards or downwards, formed in a given fixed distance from the edge of the pocket portion to the outer side in this manner enables adjusting a flow of the source gas in the peripheral portion of the semiconductor substrate, and a layer thickness of an epitaxial layer in the peripheral portion of the semiconductor substrate can be controlled.

Therefore, for example, even if uniformity of the layer thickness of the outer peripheral portion is degraded under given epitaxial growth conditions, the uniformity of the layer thickness of the epitaxial layer of the outer peripheral portion of the semiconductor substrate can be improved by adjusting a susceptor shape alone without changing the epitaxial growth conditions, thereby increasing a degree of freedom of control. That is, the control can be facilitated, the stable epitaxial layer having a uniform layer thickness can be vapor-grown, thus improving a production yield.

Further, when the flatness of the outer peripheral portion of the semiconductor substrate before performing the epitaxial growth is poor, using the susceptor according to the present invention enables adjusting a layer thickness distribution of the epitaxial layer in the peripheral portion of the semiconductor substrate to correct the shape of the outer peripheral portion of the semiconductor substrate, whereby the epitaxial wafer having the highly flat surface can be stably provided.

Here, it is preferable for a length of the taper portion from the edge of the pocket portion to the outer side to be a length that is 1% or above and less than 7.5% or, more preferably, 2.5% or above and less than 7.5% of a diameter of the semiconductor substrate.

When the length from the end to the outer side of the pocket portion is 1% or above and less than 7.5% of the diameter of the semiconductor substrate or, more preferably, 2.5% or above and less than 7.5% of the same in this manner, the layer thickness adjusting effect of the peripheral portion of the semiconductor substrate can be sufficiently enhanced, thereby greatly contributing to manufacture of the epitaxial wafer having high flatness.

Furthermore, it is preferable for a height of the taper portion to be equal to or below 30% of a thickness of the semiconductor substrate.

When the height of the taper portion is equal to or below 30% of the thickness of the semiconductor substrate as described above, turbulence of a flow of a source gas at the peripheral portion of the semiconductor substrate can be assuredly suppressed, and the epitaxial wafer having the epitaxial layer with a uniform layer thickness formed thereon can be more assuredly manufactured.

Moreover, the taper can be continuously formed over an entire circumference of the pocket portion or can be intermittently formed along a circumferential direction of the pocket portion.

When the susceptor having the taper continuously formed over an entire circumference of the pocket portion is provided, the layer thickness of the outer peripheral portion of the semiconductor substrate can be uniformly adjusted over an entire circumference of the semiconductor substrate.

In case of the susceptor having the taper intermittently formed along a circumferential direction of the pocket portion, the layer thickness of a part of the outer peripheral portion of the semiconductor substrate can be adjusted, and hence the epitaxial wafer having good flatness can be obtained by appropriately selecting the susceptor in accordance with the surface shape of the semiconductor substrate before vapor-phase growth.

Further, it is preferable for a depth of the pocket portion of the susceptor to be 0.9 to 1.1-fold of the thickness of the semiconductor substrate.

When the susceptor having the pocket portion whose depth is 0.9 to 1.1-fold of the thickness of the semiconductor substrate is adopted in this manner, the substrate thickness of the semiconductor substrate that is subjected to the epitaxial growth can be substantially made equal to the pocket depth of the pocket portion, thereby further highly accurately performing the control over the layer thickness of the outer peripheral portion of the semiconductor substrate.

Furthermore, according to the present invention, there is provided an epitaxial wafer manufacturing apparatus which is an epitaxial wafer manufacturing apparatus configured to effect vapor-phase growth of an epitaxial layer on a main front surface of a semiconductor substrate, comprising at least: a reaction vessel; a source gas introducing tube; an exhaust tube; a heating device; and a susceptor according to the present invention.

As described above, when the apparatus for manufacturing an epitaxial wafer provided with the susceptor that supports the semiconductor substrate according to the present invention is used, the epitaxial layer at the outer peripheral portion of the semiconductor substrate can be uniformly formed by vapor-growing the epitaxial layer on the main front surface of the semiconductor substrate without changing the epitaxial growth conditions.

Moreover, the epitaxial layer thickness at the outer peripheral portion of the semiconductor substrate can be adjusted in accordance with the outer peripheral shape of the semiconductor substrate. That is, since the shape of the outer peripheral portion of the semiconductor substrate can be corrected, the highly flat epitaxial wafer can be stably provided.

Additionally, according to the present invention, there is provided an epitaxial wafer manufacturing method for effecting vapor-phase growth of an epitaxial layer on a semiconductor substrate, wherein the semiconductor substrate is arranged in the pocket portion of a susceptor according to the present invention to effect the vapor-phase growth of the epitaxial layer in a vapor-phase growth process for effecting the vapor-phase growth of the epitaxial layer on a main front surface of the semiconductor substrate.

Further, according to the present invention, there is provided an epitaxial wafer manufacturing method for effecting vapor-phase growth of an epitaxial layer on a semiconductor substrate, wherein the semiconductor substrate is arranged in a pocket portion of a susceptor having the pocket portion in which the semiconductor substrate is arranged, and a taper portion with a taper formed such that an upper surface of the susceptor is inclined upwards or downwards from an edge of the pocket portion to an outer side; and the vapor-phase growth of the epitaxial layer is effected in a vapor-phase growth process for effecting the vapor-phase growth of the epitaxial layer on a main front surface of the semiconductor substrate.

As described above, when the susceptor having the taper portion with the taper, where the upper surface of the susceptor gradually inclines upwards or downwards, formed in a given fixed distance from the edge to the outer side of the pocket portion is used as the susceptor that supports the semiconductor substrate when vapor-growing the epitaxial layer on the semiconductor substrate, amounts of rise and sag at the outer periphery of the semiconductor substrate after forming the epitaxial layer can be adjusted, whereby the epitaxial wafer having the high flatness at not only the central portion but also the peripheral portion can be manufactured.

In particular, since the rise and the sag of the outer peripheral portion can be easily controlled by adjusting the height of the taper and a position in the outer peripheral portion of the epitaxial layer at which the rise and the sag occur can be controlled by adjusting the length from the edge to the outer side of the pocket portion, the surface shape of the epitaxial layer can be controlled by just adjusting the taper shape and the like of the susceptor in accordance with the surface shape of the semiconductor substrate before the vapor-phase growth, thereby easily manufacturing the epitaxial wafer having the high flatness.

As described above, according to the present invention, the thickness of the epitaxial layer at the outer peripheral portion of the semiconductor substrate can be uniformed. Furthermore, a distribution of the epitaxial layer at the outer peripheral portion can be adjusted in accordance with the outer peripheral shape of the semiconductor substrate before the epitaxial growth, thus stably supplying the highly flat epitaxial wafer.

### BRIEF DESCRIPTION OF THE DRAWINGS

FIG. 1 is a schematic view showing an example of an epitaxial manufacturing apparatus according to the present invention;

FIG. 2 is a schematic view showing another mode of the epitaxial manufacturing apparatus according to the present invention;

FIG. 3 is a schematic view showing a first mode of a susceptor according to the present invention;

FIG. 4 is a schematic view showing a second mode of the susceptor according to the present invention;

FIG. 5 is a view showing an example when the susceptor according to the present invention is seen from above (when a taper portion is provided on the entire circumference);

FIG. 6 is a view showing another example when the susceptor according to the present invention is seen from above (when the taper portion is intermittently provided);

FIG. 7 is a view showing a layer thickness distribution of an outer peripheral portion of a silicon epitaxial layer according to each of Examples 1 to 5 and Comparative Examples 2 and 3;

FIG. 8 is a view showing a layer thickness distribution of an outer peripheral portion of a silicon epitaxial layer according to each of Examples 6 to 9 and Comparative Examples 1 and 2;

FIG. 9 is a view showing a layer thickness distribution of an outer peripheral portion of a silicon epitaxial layer according to each of Comparative Examples 1 to 3;

FIG. 10 is a view showing an outline of a cross-sectional shape of a conventional susceptor;

FIG. 11 is a view showing an outline of a cross-sectional shape of a conventional susceptor having a large pocket depth; and

FIG. 12 is a view showing an outline of a cross-sectional shape of a conventional susceptor having a small pocket depth.

### DESCRIPTION OF EMBODIMENTS

Although the present invention will now be described hereinafter in detail with reference to the drawings, the present invention is not restricted thereto.

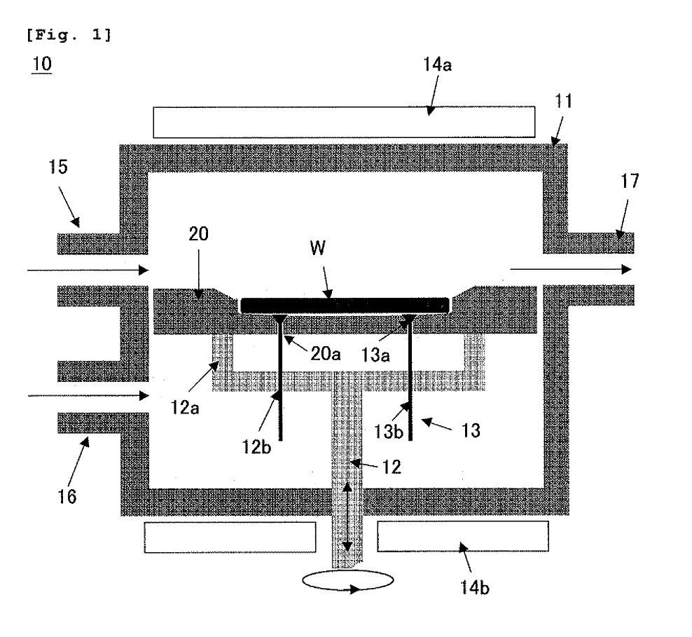

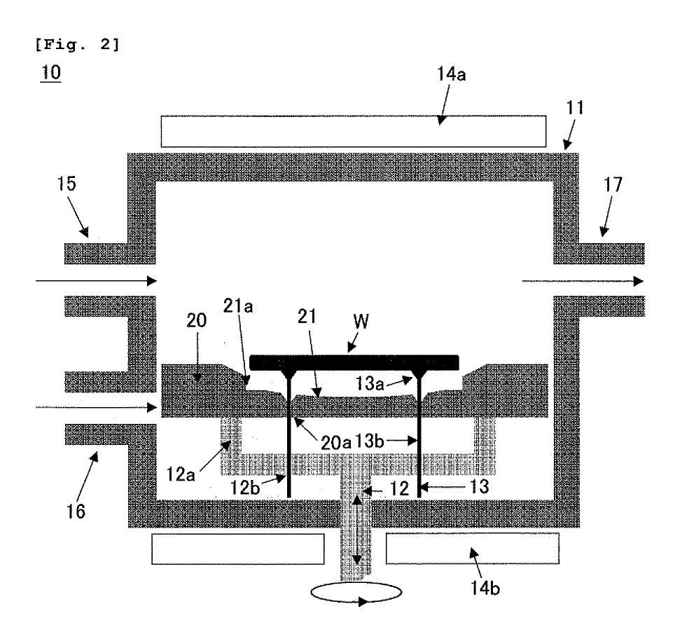

A description will be first given as to a single-wafer processing type epitaxial wafer manufacturing apparatus as an example of an epitaxial wafer manufacturing apparatus according to the present invention with reference to FIG. 1 and FIG. 2.

As shown in FIG. 1, an epitaxial wafer manufacturing apparatus 10 comprises at least: a susceptor 20 (which will be described later in detail), a reaction vessel 11 in which the susceptor 20 is arranged; a susceptor support member 12 that supports, rotates, and moves up and down the susceptor 20; lift pins 13 that pierce front and back sides of the susceptor 20, are provided so as to be capable of moving up and down with respect to the susceptor 20, and attach or detach a semiconductor substrate W (which may be referred to as a substrate W hereinafter) onto or from the susceptor 20 in accordance with upward or downward movement while supporting this substrate W; heating devices 14a and 14b (which are specifically, e.g., halogen lamps) for heating the substrate W to a desired growth temperature at the time of a vapor-phase growth; a vapor-phase growth source gas introducing tube 15 through which a vapor-phase growth gas containing a source gas (which is specifically, e.g., trichlorosilane) and a carrier gas (which is specifically, e.g., hydrogen) is introduced to a region above the susceptor 20 in the reaction vessel 11 and supplied onto a main front surface of the substrate W on the susceptor 20; a purge gas introducing tube 16 which is provided on the same side as this vapor-phase growth gas introducing tube 15 with respect to the reaction vessel 11 and through which a purge gas (which is specifically, e.g., hydrogen) is led into a region below the susceptor 20 in the reaction vessel 11; and an exhaust tube 17 which is provided on the opposite side of the purge gas introducing tube 16 and the source gas introducing tube 15 with respect to the reaction vessel 11 and through which the gas (the vapor-phase growth source gas and the purge gas) is exhausted from the reaction vessel 11.

In these members, the susceptor 20 supports the substrate W at the time of vapor-phase growth, and it is constituted of, e.g., graphite covered with a silicon carbide.

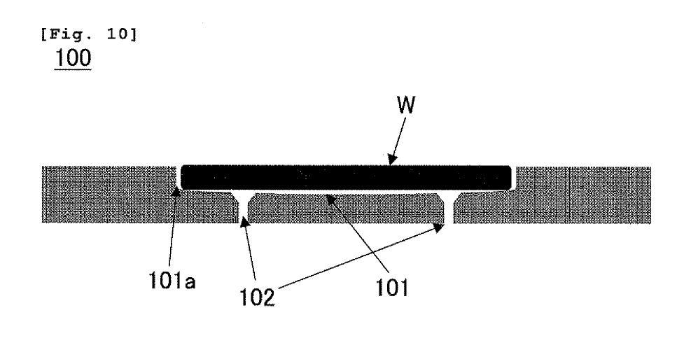

FIG. 10 shows a shape of a general conventional susceptor.

The conventional susceptor 100 is formed into, e.g., a substantially discoid shape, and a pocket portion 101 (a concave portion having a circular shape when seen in a plan view) for positioning the substrate W on the main front surface is formed on this main front surface. A bottom surface of this pocket portion 101 may have a flat surface or a concave curved surface. Further, there have been proposed a pocket portion in which a part of the bottom surface of the pocket portion 101 near a pocket edge bottom portion 101a is formed into a flat surface and the inner side is formed into a concave curved surface, and a pocket portion in which a hole pierced to a back surface of the susceptor 100 is provided near the pocket edge bottom portion 101a.

Furthermore, as shown in FIG. 10, lift pin through hole portions 102 which are formed into a state piercing the back surface of the susceptor 100 and into which the lift pins are inserted are formed on a bottom surface of the pocket portion 101 of the susceptor 100. The lift pin thorough hole portions 102 are arranged at three positions on the pocket portion 101 at equal angular intervals.

Here, for example, as shown in FIG. 1, the lift pin 13 includes a body portion 13b formed into, e.g., a round bar shape and a head portion 13a which is formed at an upper end of the body portion 13b and supports the substrate W from a lower surface side. In these portions, the head portion 13a has a diameter larger than that of the body portion 13b so that the substrate W can be easily supported.

Furthermore, when the lift pin 13 is inserted into the lift pin through hole portion 20a from a lower end thereof, the head portion 13b is prevented from being removed downwards by an edge portion of the lift pin through hole portion 20a and supported by the susceptor 20, and the body portion 13b is suspended from the lift pin through hole 20a. It is to be noted that the body portion 13b of the lift pin 13 is also inserted into a through hole 12b provided in a support arm 12a of the susceptor support member 12.

Moreover, the susceptor support member 12 has a plurality of support arms 12a in a radial pattern and supports the susceptor 20 from a lower surface side by using the support arms 12a. As a result, an upper surface of the susceptor 20 is maintained in a substantially horizontal state.

The epitaxial manufacturing apparatus 10 is constituted as described above.

Additionally, when this epitaxial wafer manufacturing apparatus 10 is used to perform vapor-phase growth in the following manner, a silicon epitaxial layer can be formed on the main front surface of the substrate W to manufacture a silicon epitaxial wafer.

First, the substrate W is supported by the susceptor 20 in the reaction vessel 11.

To this end, in order to transfer the substrate W onto the lift pins 13, the respective lift pins 13 are first relatively moved up with respect to the susceptor 20 in such a manner that these pins protrude upwards from the upper surface of the susceptor 20 for the same length. Further, the susceptor 20 may be moved down in accordance with downward movement of the susceptor support member 12. In a process of this downward movement, after the lower end portions of the lift pins 13 reach, e.g., an inner bottom surface of the reaction vessel 11, the lift pins 13 cannot further move down, but the susceptor 20 can further move down.

Therefore, the lift pins 13 relatively move up with respect to the susceptor 20, and then the lift pins and the susceptor have such a positional relationship as shown in FIG. 2 (a state without the substrate W in FIG. 2).

Subsequently, the substrate W is conveyed into the reaction vessel 11 by a non-illustrated transfer device, and the substrate W is supported by the head portions 13a of the respective lift pins 13 after the moving-up operation with the main surface facing the upper side (the state in FIG. 2).

Then, to support the substrate W on the susceptor 20, the respective lift pins 13 are relatively moved down with respect to the susceptor 20. Therefore, the transfer device is retracted and, on the other hand, the susceptor 20 is moved up in accordance with the upward movement of the susceptor support member 12. In a process of this upward movement, when the pocket edge bottom portion 21a of the pocket portion 21 reaches a main back surface of the substrate W, the substrate W supported on the head portions 13a of the lift pins 13 is changed to a state that the substrate W is supported at a position near the pocket edge bottom surface 21a of the pocket portion 21.

Further, when an edge portion of each lift pin through hole 20a reaches the head portion 13a of each lift pin 13, the lift pins 13 supported by the inner bottom surface of the reaction vessel 11 until now is changed to a state that the lift pins 13 are supported by the susceptor 20.

When the substrate W is supported by the susceptor 20 in this manner, vapor-phase growth is performed.

First, the substrate W is rotated in accordance with rotation of the susceptor 20 that is effected by driving the susceptor support member 12 to rotate about a perpendicular axis, the vapor-phase growth gas is substantially horizontally supplied to the main front surface of the substrate W through the source gas introducing tube 15 while heating the substrate W on the susceptor 20 to a desired growth temperature by the heating devices 14a and 14b and, on the other hand, the purge gas is substantially horizontally introduced to the lower side of the susceptor 20 through the purge gas introducing tube 16.

Therefore, during the vapor-phase growth, a vapor-phase growth gas current is formed on the upper side of the susceptor 20 and a purge gas current is formed on the lower side of the same in substantially parallel to the susceptor 20 and the substrate W, respectively. When the vapor-phase growth is carried out in this manner, an epitaxially layer can be formed on the main front surface of the substrate W to manufacture an epitaxial wafer.

After the epitaxial wafer is manufactured in this manner, the manufactured epitaxial wafer is carried to the outside of the reaction vessel 11.

That is, after the rotation of the susceptor 20 is stopped, the susceptor support member 12 is moved down to protrude the respective lift pins 13 above the susceptor 20 for the same lengths as shown in FIG. 2, and the substrate W is moved above the pocket portion 21 of the susceptor 20 in accordance with this protruding operation. Furthermore, the substrate W is carried out by the non-illustrated transfer device.

Here, during the vapor-phase growth, the vapor-phase growth gas is introduced from the vapor-phase growth gas introducing tube 15 to flow along the surface of the susceptor 20 and carried to an edge portion of the substrate W. A growth rate of the epitaxial layer near the edge of the substrate W is greatly dependent on concentration or a flow velocity of the vapor-phase growth gas near the edge of the substrate W.

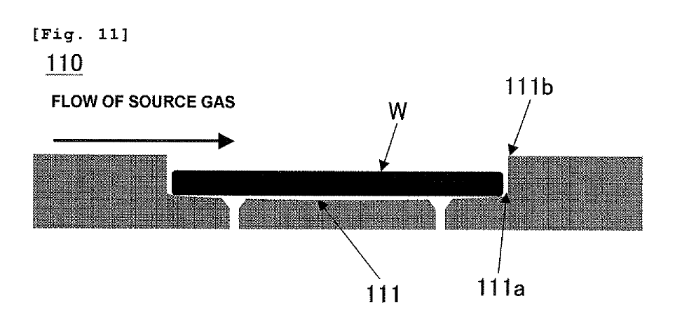

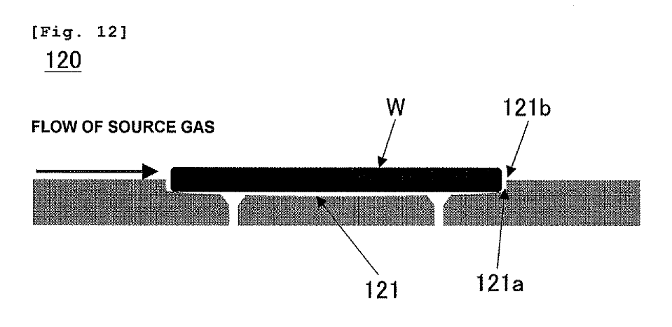

In general, as shown in FIG. 11 or FIG. 12, there is adopted a method for changing a flow of the vapor-phase growth gas near the edge of the substrate W by adjusting pocket depths of pocket portions 111 and 121 (differences in height between pocket edge bottom portions 111a and 121a and pocket edge upper portions 111b and 121b of the pocket portions 111 and 121) in the susceptors 110 and 120 for supporting the substrate W, thereby adjusting an epitaxial growth rate near the edge of the substrate W.

For example, as shown in FIG. 11, when the pocket depth of the susceptor 110 is larger than a thickness of the substrate W as shown in FIG. 11, concentration of the vapor-phase growth gas supplied to the edge portion of the substrate W is lowered, and the epitaxial growth rate near the edge of the substrate W is reduced.

However, a step is produced between the substrate W and the pocket edge upper portion 111b of the pocket portion 111, the flow of the vapor-phase growth gas thereby becomes turbulent, and the reduction in epitaxial growth rate of the substrate W extends to an inner region from the edge portion of the substrate W. Therefore, the epitaxial growth rate at an outer peripheral portion of the substrate W cannot be accurately controlled.

Further, as shown in FIG. 12, when the pocket depth of the susceptor 120 is smaller than the thickness of the substrate W, the concentration of the vapor-phase growth gas supplied to the edge portion of the substrate W rises, and the epitaxial growth rate near the edge of the substrate W is increased.

However, a step is formed between the substrate W and the pocket edge upper portion 121b of the pocket portion 121 in the susceptor, the flow of the vapor-phase growth gas thereby becomes turbulent, and the increase in epitaxial growth rate of the substrate W extends to the inner region from the edge portion of the substrate W. Therefore, likewise, the epitaxial growth rate at the outer peripheral portion of the substrate W cannot be accurately controlled.

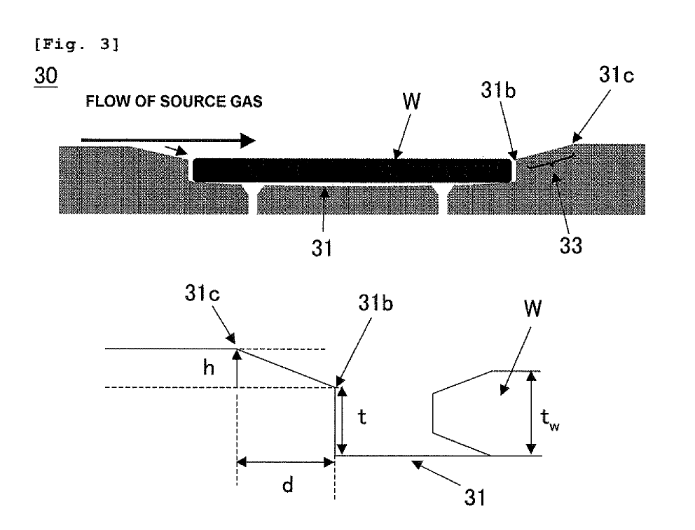

On the other hand, as shown in FIG. 3, a susceptor 30 according to a first embodiment of the present invention maintains a height of a pocket edge upper portion 31b of a pocket portion 31 to be substantially equal to a height of a main front surface of the substrate W and the susceptor has a taper portion 33 having a taper, where an upper surface of the susceptor is gradually inclined toward the outer side of the pocket portion 31, formed from the pocket edge upper portion 31b to a taper portion end 31c.

When the epitaxial wafer manufacturing apparatus provided with the susceptor that supports a semiconductor substrate according to the present invention is used to perform vapor-phase growth of an epitaxial layer on the main front surface of the semiconductor substrate in this manner, the epitaxial layer at an outer peripheral portion of the substrate can be uniformly formed without changing epitaxial growth conditions.

Further, a thickness of the epitaxial layer at the outer peripheral portion of the semiconductor substrate can be adjusted in accordance with an outer peripheral shape of the semiconductor substrate before the epitaxial growth. Therefore, the shape of the outer peripheral portion of the semiconductor substrate can be corrected without changing vapor-phase growth conditions, and the epitaxial wafer that is highly flat even at the outer peripheral portion in particular can be stably provided.

Here, when a difference h in height between the pocket edge upper portion 31b of the pocket portion 31 and the taper end 31c (a height of the taper portion itself) is adjusted, an epitaxial growth rate near the edge of the substrate can be suppressed to a desired level.

For example, the height h of the taper portion 33 can be set to 30% or below of the thickness t_{w} of the semiconductor substrate W. As a result, since a flow of the source gas can be assuredly suppressed from becoming turbulent, it is possible to provide the susceptor that is suitable for more assuredly and stably manufacturing the epitaxial wafer having the epitaxial layer with a uniform layer thickness formed thereon.

Further, when a length d from a position of the taper end 31c to the pocket edge upper portion 31b of the pocket portion 31 in which the semiconductor substrate is arranged is adjusted, the epitaxial growth rate near the edge of the substrate from the edge of the substrate to a desired region can be suppressed. For example, when the length d is increased, a start point at which the layer thickness varies at the peripheral portion of the semiconductor substrate can be changed to a position close to the edge of the semiconductor substrate. Furthermore, when the length d is reduced, the start point at which the layer thickness varies at the peripheral portion of the semiconductor substrate can be changed to a position far from the edge of the semiconductor substrate.

For example, in the taper portion 33, the length d from the pocket edge upper portion 31b to the outer side can be set to a length that is equal to or above 1% and less than 7.5% of a diameter of the semiconductor substrate or more preferably equal to or above 2.5% and less than 7.5% of the same. As a result, a vapor-phase growth rate near the pocket edge can be assuredly controlled, and the susceptor that enables manufacturing the epitaxial wafer having excellent flatness can be provided.

Moreover, a depth t of the pocket portion 31 can be 0.9 to 1.1-fold of the thickness t_{w} of the semiconductor substrate.

As a result, the substrate thickness t_{w} of semiconductor substrate that is subjected to the epitaxial growth can be nearly equal to the pocket depth t of the pocket portion, thereby highly accurately controlling the layer thickness at the outer peripheral portion of the semiconductor substrate W.

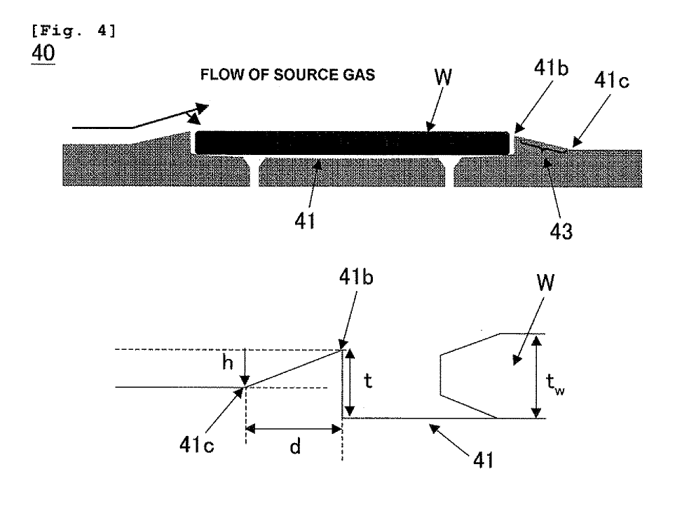

Additionally, as shown in FIG. 4, a susceptor 40 according to a second embodiment of the present invention maintains a height of a pocket edge upper portion 41b of a pocket portion 41 to be substantially equal to a height of a main front surface of a substrate W (t≈t_{w}), and the susceptor has a taper portion 43 having a taper, where an upper surface of the susceptor is gradually downwardly inclined toward the outer side of the pocket portion 41, formed from the pocket edge upper portion 41b to a taper end 41c.

In such a susceptor 40, an epitaxial growth rate near an edge of the substrate W can be increased from the edge of the substrate W to a desired region by adjusting a diameter of the taper end 41c (i.e., a length d of the taper portion 43).

Further, the epitaxial growth rate near the edge of the substrate W can be increased to a desired level by adjusting a difference h in height between the pocket edge upper portion 41b of the pocket portion 41 and the taper end 41c (a height of the taper portion 43 itself).

Here, as described above, adjusting the height h of the taper portion 43 in the range of 30% or below of the thickness t, of the substrate W enables assuredly avoiding a possibility that a flow of a vapor-phase growth gas is greatly disturbed.

Furthermore, when the length d of the taper portion 43 is also adjusted in the range of 1% or above and less than 7.5% of a diameter of the substrate W or more preferably 2.5% or above and less than 7.5% of the same, the growth rate near the edge can be likewise sufficiently controlled, thus easily and stably effecting vapor-phase growth of an epitaxial layer having a uniform layer thickness.

Moreover, when a pocket depth t of the susceptor 40 is set to the range of 0.9 to 1.1-fold of the thickness t_{w} of the substrate, the layer thickness of the outer peripheral portion of the semiconductor substrate W can be highly accurately controlled.

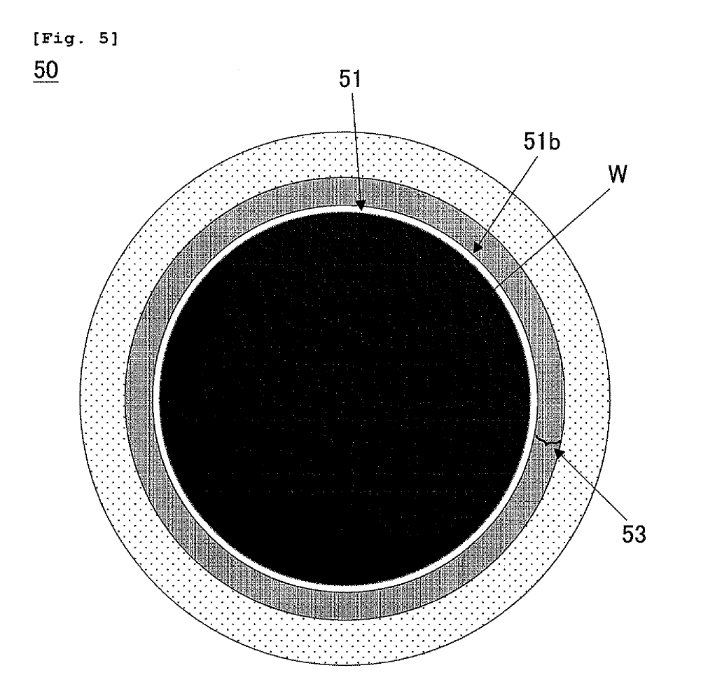

Additionally, in case of uniformly adjusting the layer thickness of the outer peripheral portion of the semiconductor substrate W on the entire circumference of the semiconductor W, it is good to continuously form a taper portion 53 from a pocket edge upper portion 51b to the outer side of a susceptor 50 over the entire circumference of a pocket portion 51 where the semiconductor substrate W is arranged as shown in FIG. 5.

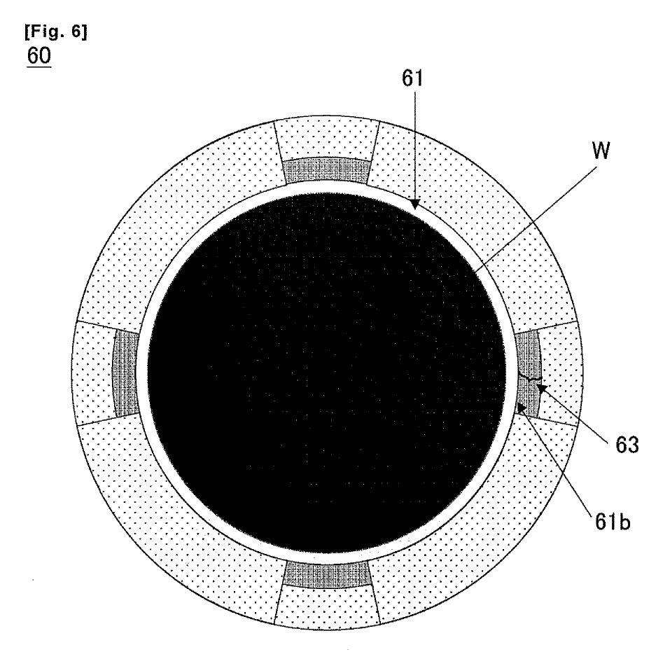

Further, when adjusting a layer thickness of a part of the outer peripheral portion of the semiconductor substrate W, it is good to intermittently form a taper portion 63 from a pocket edge upper portion 61b to the outer side of a susceptor 60 along the circumferential direction of the pocket edge upper portion 61b of the pocket portion 61 in a region corresponding to a portion where the layer thickness of the outer peripheral portion of the semiconductor substrate W is adjusted in the pocket portion 61 in which the semiconductor substrate W is arranged as shown in FIG. 6.

As described above, in the present invention, since the shape of the epitaxial layer at the peripheral portion of the semiconductor substrate can be adjusted by adjusting the height h of the taper portion itself, the length d from the end of the taper to the pocket edge of the pocket portion in which the semiconductor substrate is arranged, the depth t of the pocket portion, a direction of the taper, and presence/absence of the taper in the circumferential direction, adjusting these factors in accordance with the various substrate/vapor-phase growth conditions enables fabricating the flat epitaxial wafer.

### EXAMPLES

Although the present invention will be more specifically explained hereinafter in conjunction with examples and comparative examples, the present invention is not restricted thereto.

### Examples 1 to 5

Such a susceptor as shown in FIG. 3 was fabricated. A pocket depth t of the susceptor was set to 800 μm close to a thickness of a silicon single crystal substrate, a height h of a taper was fixed to 100 μm, and a taper length (a length from a pocket edge to an outer side) d was set to d=22.5 mm in Example 1, d=15 mm in Example 2, d=10 mm in Example 3, d=7.5 mm in Example 4, and d=3 mm in Example 5 to fabricate five types of susceptors.

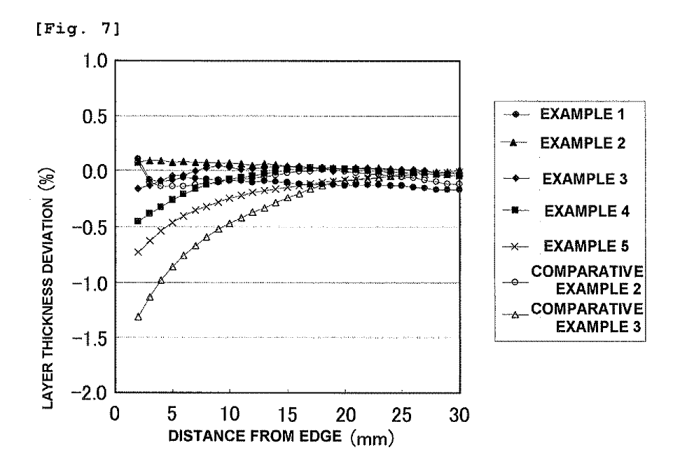

Table 1 collectively shows the parameters of each susceptor. It is to be noted that Table 1 and FIG. 7, which will be described later, show parameters of the susceptors according to later-described Comparative Examples 2 and 3 and variations in thicknesses of silicon epitaxial layers when these susceptors are used for comparison.

TABLE 1

| | | | | Ratio of taper |
|---|---|---|---|---|
| | | | | length d to |
| | | Taper | Taper | semiconductor |
| | Pocket | height | length | substrate |
| | depth t [μm] | h [μm] | d [mm] | diameter [%] |
| Example 1 | 800 | 100 | 22.5 | 7.5 |
| Example 2 | 800 | 100 | 15.0 | 5.0 |
| Example 3 | 800 | 100 | 10.0 | 3.3 |
| Example 4 | 800 | 100 | 7.5 | 2.5 |
| Example 5 | 800 | 100 | 3.0 | 1.0 |
| Comparative | 800 | — | — | — |
| Example 2 | | | | |
| Comparative | 900 | — | — | — |
| Example 3 | | | | |

Further, the fabricated susceptor was mounted at a position of the susceptor in such an epitaxial manufacturing apparatus as shown in FIG. 1, and a P⁻-type silicon epitaxial layer having a thickness of approximately 5 μm was vapor-grown on a main front surface of a P⁺-type silicon single crystal substrate having a diameter of 300 mm, an resistivity of 0.01 to 0.02 Ω·cm, and a thickness of 775 μm by using each susceptor.

Then, a silicon epitaxial layer thickness measuring device QS3300EG manufactured by Nanometrics that uses Fourier infrared spectroscopy was adopted to measure the range of 2 mm to 30 mm of an outer periphery of the silicon substrate at a pitch of 1 mm, whereby a thickness distribution of the silicon epitaxial layer was measured. FIG. 7 shows its result. In FIG. 7, a measurement value at each point was divided by an average value of all measurement points, a value obtained by subtracting 1 from this divided value was shown in percentage terms, and it was determined as an index representing a variation in thickness of the epitaxial layer.

As shown in FIG. 7, in case of Example 1 in which the taper length d is increased, outer periphery sag effect obtained by formation of the taper was weakened, and a layer thickness distribution close to that of Comparative Example 2 was provided.

Conversely, in case of Example 5 where the taper length d is reduced, the outer periphery sag effect obtained by formation of the taper was intensified, and it was revealed that a layer thickness distribution close to that of Comparative Example 3 was provided.

As described above, it was found out that a desired sag position can be obtained by adjusting the taper length d to an appropriate value, and the layer thickness distribution that is substantially flat to the outer periphery can be obtained in case of Example 2.

### Examples 6 to 9

Such a susceptor as shown in FIG. 4 was fabricated. A pocket depth t of the susceptor was set to 800 μm close to a thickness of a silicon single crystal substrate, a height h of a taper was fixed to 100 μm, and a taper length (a length from a pocket edge to an outer side) d was set to d=22.5 mm in Example 6, d=15 mm in Example 7, d=7.5 mm in Example 8, and d=3 mm in Example 9 to fabricate four types of susceptors.

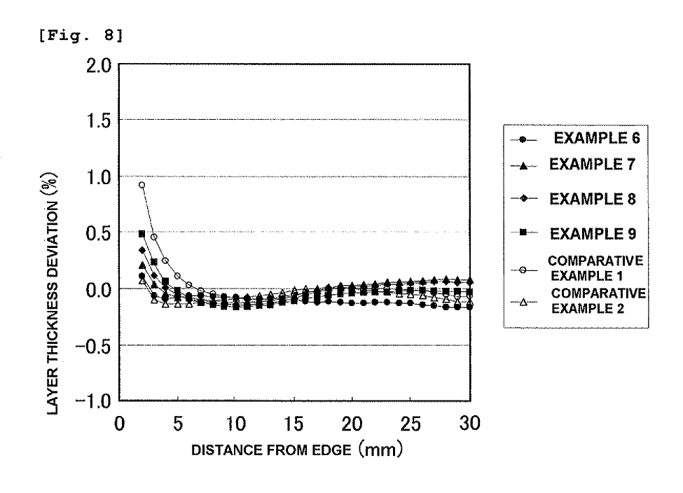

Table 2 collectively shows the parameters of each susceptor. It is to be noted that Table 2 and FIG. 8, which will be described later, show parameters of the susceptors according to later-described Comparative

Examples 1 and 2 and variations in thickness of silicon epitaxial layers when these susceptors are used for comparison.

TABLE 2

| | | | | Ratio of taper |
|---|---|---|---|---|
| | | | | length d to |
| | | Taper | Taper | semiconductor |
| | Pocket | height | length | substrate |
| | depth t [μm] | h [μm] | d [mm] | diameter [%] |
| Example 6 | 800 | 100 | 22.5 | 7.5 |
| Example 7 | 800 | 100 | 15.0 | 5.0 |
| Example 8 | 800 | 100 | 7.5 | 2.5 |
| Example 9 | 800 | 100 | 3.0 | 1.0 |
| Comparative | 700 | — | — | — |
| Example 1 | | | | |
| Comparative | 800 | — | — | — |
| Example 2 | | | | |

Furthermore, the fabricated susceptor was mounted at a position of the susceptor in such an epitaxial manufacturing apparatus as shown in FIG. 1, and a P⁻-type silicon epitaxial layer having a thickness of approximately 5 μm was vapor-grown on a main front surface of a P⁺-type silicon single crystal substrate having a diameter of 300 mm, a resistivity of 0.01 to 0.02 Ω·cm, and a thickness of 775 μm by using each susceptor.

Then, a silicon epitaxial layer thickness measuring device QS3300EG manufactured by Nanometrics that uses Fourier infrared spectroscopy was adopted to measure the range of 2 mm to 30 mm of an outer periphery of the silicon substrate at a pitch of 1 mm, whereby a thickness distribution of the silicon epitaxial layer was measured. FIG. 8 shows its result. In FIG. 8, like

FIG. 7, a measurement value at each point was divided by an average value of all measurement points, a value obtained by subtracting 1 from this divided value was shown in percentage terms, and this value was determined as an index representing a variation in thickness of the epitaxial layer.

As shown in FIG. 8, in case of Example 6 in which the taper length d is increased, outer periphery rise effect obtained by formation of the taper was weakened, and a layer thickness distribution close to that of Comparative Example 2 was provided.

Conversely, in case of Example 9 where the taper length d is reduced, the outer periphery rise effect obtained by formation of the taper was intensified, and it was revealed that a layer thickness distribution close to that of Comparative Example 1 was provided.

As described above, it was found out that a desired rise position can be obtained by adjusting the taper length d to an appropriate value.

### Comparative Examples 1 to 3

Such a susceptor as shown in FIG. 10 was fabricated. A depth t of a pocket portion of the susceptor was set to 700 μm in Comparative Example 1, 800 μm in Comparative Example 2, and 900 μm in Comparative Example 3 to prepare three types of susceptors.

Furthermore, each of these susceptors was mounted at a position of the susceptor in the epitaxial manufacturing apparatus depicted in FIG. 1 in place of each susceptor used in the examples, and a P⁻-type silicon epitaxial layer having a thickness of approximately 5 μm was vapor-grown on a main front surface of a P⁺-type silicon single crystal substrate having a diameter of 300 mm, a resistivity of 0.01 to 0.02 Ω·cm, and a thickness of 775 μm by using each susceptor.

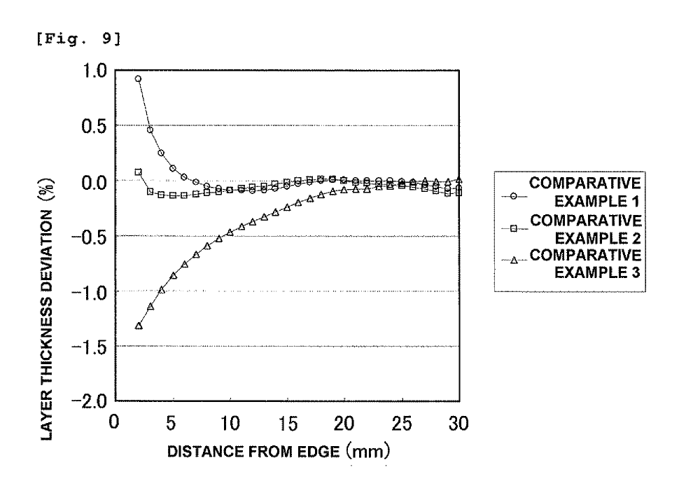

Then, a silicon epitaxial layer thickness measuring device QS3300EG manufactured by Nanometrics that uses Fourier infrared spectroscopy was adopted to measure the range of 2 mm to 30 mm of an outer periphery of the silicon substrate at a pitch of 1 mm, whereby a thickness distribution of the silicon epitaxial layer was measured. FIG. 9 shows its result. In FIG. 9, like FIG. 7 and FIG. 8, a measurement value at each point was divided by an average value of all measurement points, a value obtained by subtracting 1 from this divided value was shown in percentage terms, and this value was determined as an index representing a variation in thickness of the epitaxial layer.

As shown in FIG. 9, when the pocket depth is changed from a small depth to a large depth, the layer thickness distribution of the silicon epitaxial layer is changed from the rise shape to the sag shape.

However, it was revealed that the sag and rise positions are likewise greatly changed and simultaneously controlling sag and rise amounts and these positions of the epitaxial layer at the outer peripheral portion to flatten the surface is difficult.

It is to be noted that the present invention is not restricted to the foregoing embodiments. The above-described embodiments are just illustrative examples, and any examples that have substantially the same configuration and exercise the same functions and effects as the technical concept described in claims of the present invention are included in the technical scope of the present invention.

1-10. (canceled)

11. A vapor-phase growth semiconductor substrate support susceptor for supporting a semiconductor substrate at the time of vapor-phase growth,
wherein the susceptor comprises a pocket portion in which the semiconductor substrate is arranged and has a taper portion having a taper formed such that an upper surface of the susceptor is inclined upwards or downwards from an edge of the pocket portion to an outer side.

12. The vapor-phase growth semiconductor substrate support susceptor according to claim 11, wherein a length of the taper portion from the edge of the pocket portion to the outer side is a length that is 1% or above and less than 7.5% of a diameter of the semiconductor substrate.

13. The vapor-phase growth semiconductor substrate support susceptor according to claim 11, wherein the length of the taper portion from the edge of the pocket portion to the outer side is a length that is 2.5% or above and less than 7.5% of the diameter of the semiconductor substrate.

14. The vapor-phase growth semiconductor substrate support susceptor according to claim 12, wherein the length of the taper portion from the edge of the pocket portion to the outer side is a length that is 2.5% or above and less than 7.5% of the diameter of the semiconductor substrate.

15. The vapor-phase growth semiconductor substrate support susceptor according to claim 11, wherein a height of the taper portion is equal to or below 30% of a thickness of the semiconductor substrate.

16. The vapor-phase growth semiconductor substrate support susceptor according to claim 12, wherein a height of the taper portion is equal to or below 30% of a thickness of the semiconductor substrate.

17. The vapor-phase growth semiconductor substrate support susceptor according to claim 13, wherein a height of the taper portion is equal to or below 30% of a thickness of the semiconductor substrate.

18. The vapor-phase growth semiconductor substrate support susceptor according to claim 14, wherein a height of the taper portion is equal to or below 30% of a thickness of the semiconductor substrate.

19. The vapor-phase growth semiconductor substrate support susceptor according to claim 11, wherein the taper is continuously formed over an entire circumference of the pocket portion.

20. The vapor-phase growth semiconductor substrate support susceptor according to claim 11, wherein the taper is intermittently formed along a circumferential direction of the pocket portion.

21. The vapor-phase growth semiconductor substrate support susceptor according to claim 11, wherein a depth of the pocket portion of the susceptor is 0.9 to 1.1-fold of the thickness of the semiconductor substrate.

22. An epitaxial wafer manufacturing apparatus configured to effect vapor-phase growth of an epitaxial layer on a main front surface of a semiconductor substrate, comprising at least:
a reaction vessel; a source gas introducing tube; an exhaust tube; a heating device; and a susceptor according to claim 11.

23. An epitaxial wafer manufacturing method for effecting vapor-phase growth of an epitaxial layer on a semiconductor substrate,
wherein the semiconductor substrate is arranged in the pocket portion of a susceptor according to claim 11 to effect the vapor-phase growth of the epitaxial layer in a vapor-phase growth process for effecting the vapor-phase growth of the epitaxial layer on a main front surface of the semiconductor substrate.

24. An epitaxial wafer manufacturing method for effecting vapor-phase growth of an epitaxial layer on a semiconductor substrate,
wherein the semiconductor substrate is arranged in a pocket portion of a suseeptor having the pocket portion in which the semiconductor substrate is arranged, and a taper portion with a taper formed such that an upper surface of the susceptor is inclined upwards or downwards from an edge of the pocket portion to an outer side; and the vapor-phase growth of the epitaxial layer is effected in a vapor-phase growth process for effecting the vapor-phase growth of the epitaxial layer on a main front surface of the semiconductor substrate.
